(19) United States
(12) Patent Application Publication
(10) Pub. No.: US 2007/0059863 A1
(43) Pub. Date: Mar. 15, 2007

(54) Method of manufacturing quad flat non-leaded semiconductor package

(75) Inventors: Chun-Yuan Li, Taichung Hsien (TW); Fu-Di Tang, Taichung Hsien (TW); Chien-Ping Huang, Hsinchu Hsein (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/486,569

(22) Filed: Jul. 14, 2006

(30) Foreign Application Priority Data
Sep. 15, 2005 (TW) 094131778

(51) Int. Cl. H01L 21/00

(52) U.S. Cl. 438/113

(57) ABSTRACT

A method of manufacturing a quad flat non-leaded semiconductor package is provided. A metal plate is prepared and is defined with predetermined positions of a plurality of electrically conductive pads. A resist layer is formed on the metal plate, and a plurality of openings are formed in the resist layer and correspond to the predetermined positions of the electrically conductive pads. A solderable metal plated layer is formed in each of the openings of the resist layer. The resist layer on the metal plate is removed. A portion of the metal plate, which is not covered by the metal plated layers, is etched using the metal plated layers as a mask. A chip is mounted on the metal plate and is electrically connected to the electrically conductive pads. A molding process is performed such that the chip and the metal plate are encapsulated by an encapsulant.

### FIELD OF THE INVENTION

The present invention relates to methods of manufacturing quad flat non-leaded semiconductor packages, and more particularly, to a method of manufacturing a quad flat non-leaded semiconductor package without performing an electroless plating process and a lithography process after a molding process.

### BACKGROUND OF THE INVENTION

Quad flat non-leaded semiconductor package as shown in FIG. 1 comprises a chip 51 mounted on a die pad 50 of a non-leaded lead frame, wherein the chip 51 is electrically connected to a plurality of electrically conductive pads 53 around the die pad 50 through bonding wires 52. The electrically conductive pads 53 in place of conventional leads are used to transmit signals from the chip 51 to an external device. Compared with a typical lead-frame-based semiconductor package using leads for signal transmission, the quad flat non-leaded semiconductor package avoids the need of bending the lead frame and thus has a reduced height, making the quad flat non-leaded semiconductor package widely employed in electronic products.

The quad flat non-leaded semiconductor package can be fabricated by a method as disclosed in U.S. Pat. No. 6,498,099. As shown in FIG. 2A, a copper plate 60 is firstly prepared. Then, as shown in FIG. 2B, an upper surface and a lower surface of the copper plate 60 are partially etched to define predetermined positions of a die pad 61 and a plurality of electrically conductive pads 62, and a nickel/palladium (Ni/Pd) layer (not shown) is plated on the copper plate 60. As shown in FIG. 2C, a chip 65 is mounted on the die pad 61 and is electrically connected to the electrically conductive pads 62 via bonding wires 66. As shown in FIG. 2D, a molding process is performed to form an encapsulant 67 for protecting the chip 65 and the bonding wires 66. As shown in FIG. 2E, a bottom surface of the copper plate 60, which is exposed from the encapsulant 67, is coated with a photoresist layer 68, wherein the photoresist layer 68 can be a dry film or a liquid film. By using the photoresist layer 68 as a mask, an etching process is performed on the copper plate 60 to separate the die pad 61 and the plurality of electrically conductive pads 62 from each other, as shown in FIG. 2F. After removing the photoresist layer 68, an electroless plating process is performed to form a solderable gold (Au) plated layer (not shown) on the copper plate 60, and a singulation process is carried out such that the quad flat non-leaded semiconductor package is obtained, as shown in FIG. 2G.

However, the above fabrication method including coating the photoresist layer 68 on the copper plate 60 and performing exposure, development and etching after the molding process, causes significant drawbacks. Firstly, performing a lithography process after the molding process does not allow the photoresist layer 68 to be directly applied over the entire panel-shaped copper plate but needs to apply the photoresist layer 68 on a strip-shaped copper plate, thereby increasing the difficulty and cost of the fabrication processes. Further, the copper plate 60 may become warped by the molding process performed in a high temperature, making the photoresist layer 68 difficult to be coated flatly on the copper plate 60. Moreover, the gold plated layer formed by electroless plating does not have strong adhesion to the copper plate 60, thereby resulting in poor solderability. These drawbacks lead to a low product yield and increased fabrication cost for the above quad flat non-leaded semiconductor package.

Therefore, the problem to be solved here is to provide a method of manufacturing a quad flat non-leaded semiconductor package, which can overcome the above drawbacks to increase the product yield and reduce the fabrication cost of the semiconductor package.

### SUMMARY OF THE INVENTION

In light of the foregoing drawbacks of the prior art, an objective of the present invention is to provide a method of manufacturing a quad flat non-leaded semiconductor package without performing a lithography process after a molding process.

Another objective of the present invention is to provide a method of manufacturing a quad flat non-leaded semiconductor package, which only needs to perform an etching process after a molding process.

Still another objective of the present invention is to provide a method of manufacturing a quad flat non-leaded semiconductor package with low cost.

A further objective of the present invention is to provide a method of manufacturing a quad flat non-leaded semiconductor package with a plated layer having better solderability.

To achieve the above and other objectives, the present invention proposes a method of manufacturing a quad flat non-leaded semiconductor package, comprising the steps of: preparing a metal plate having a first surface and an opposed second surface, wherein the first surface of the metal plate is defined with predetermined positions of a die pad and a plurality of electrically conductive pads; forming a resist layer on each of the first and second surfaces of the metal plate; forming a plurality of openings in the resist layers on the first and second surfaces of the metal plate, the openings corresponding to the predetermined positions of the die pad and the electrically conductive pads; forming a solderable metal plated layer in each of the openings of the resist layers; removing the resist layer on the first surface of the metal plate; performing an etching process on the first surface of the metal plate, such that a portion of the metal plate, which is not covered by the metal plated layers, is etched; removing the resist layer on the second surface of the metal plate; mounting a chip to the die pad on the first surface of the metal plate; electrically connecting the chip to the electrically conductive pads via a plurality of bonding wires; performing a molding process to form an encapsulant for encapsulating the chip, the bonding wires and the first surface of the metal plate; etching the second surface of the metal plate with the metal plated layers serving as a mask, so as to separate the die pad and the electrically conductive pads from each other; and performing a singulation process such that the quad flat non-leaded semiconductor package is obtained. Further, besides the electrically conductive pads, a ground ring can also be formed around the die pad, so as to provide both a grounding effect and signal transmission for the chip.

According to another embodiment of the present invention, a method of manufacturing a quad flat non-leaded semiconductor package comprises the steps of: preparing a metal plate having a first surface and an opposed second surface, wherein the first surface of the metal plate is defined with predetermined positions of a plurality of electrically conductive pads; forming a resist layer on each of the first and second surfaces of the metal plate; forming a plurality of openings in the resist layers on the first and second surfaces of the metal plate, the openings corresponding to the predetermined positions of the electrically conductive pads; forming a metal plated layer in each of the openings of the resist layers; removing the resist layer on the first surface of the metal plate; performing an etching process on the first surface of the metal plate, such that a portion of the metal plate, which is not covered by the metal plated layers, is etched; removing the resist layer on the second surface of the metal plate; mounting a flip chip on the first surface of the metal plate and electrically connecting the chip to the electrically conductive pads via a plurality of conductive bumps; performing a molding process to form an encapsulant for encapsulating the chip, the conductive bumps and the first surface of the metal plate; etching the second surface of the metal plate to separate the electrically conductive pads from each other; and performing a singulation process such that the quad flat non-leaded semiconductor package is obtained.

The resist layer can be a dry film. As the openings of the resist layers correspond to the predetermined positions of the die pad and the plurality of electrically conductive pads, the metal plated layers formed in the openings are applied on the predetermined positions of the die pad and the electrically conductive pads.

The metal plated layer has at least four layers preferably including gold/palladium/nickel/palladium (Au/Pd/Ni/Pd) layers. Also, the metal plated layers on the first and second surfaces of the metal plate serve as a mask when etching the first surface and the second surface of the metal plate.

Therefore, the method of the present invention allows a plating process of forming the metal plated layers and a lithography process to be completed on a panel-shaped metal plate, instead of a strip-shaped metal plate, before the molding process. That is, after defining the die pad and the electrically conductive pads, the fabrication processes such as die bonding, forming electrical connection and molding are performed, and then only a simple etching step is needed after the molding process to fabricate the quad flat non-leaded semiconductor package. Thus, the present invention has reduced difficulty and cost of the fabrication processes as not requiring the electroless plating and lithography processes in the prior art after the molding process, and the present invention also improves the product yield of the quad flat non-leaded semiconductor package and provides a metal plated layer having better solderability, such that the drawbacks in the prior art are solved.

### BRIEF DESCRIPTION OF DRAWINGS

The present invention can be more fully understood by reading the following detailed description of the preferred embodiments, with reference made to the accompanying drawings, wherein:

FIG. 1 (PRIOR ART) is a cross-sectional view of a conventional quad flat non-leaded semiconductor package;

FIGS. 2A to 2G (PRIOR ART) are schematic cross-sectional diagrams showing steps of a method of manufacturing a quad flat non-leaded semiconductor package as disclosed in U.S. Pat. No. 6,498,099;

FIGS. 3A to 3I are schematic cross-sectional diagrams showing steps of a method of manufacturing a quad flat non-leaded semiconductor package according to a first embodiment of the present invention;

FIGS. 4A to 4C are schematic diagrams showing a quad flat non-leaded semiconductor package according to a second embodiment of the present invention;

FIGS. 5A and 5B are schematic diagrams showing a quad flat non-leaded semiconductor package according to a third embodiment of the present invention; and

FIGS. 6A to 6I are schematic cross-sectional diagrams showing steps of a method of manufacturing a quad flat non-leaded semiconductor package according to a fourth embodiment of the present invention.

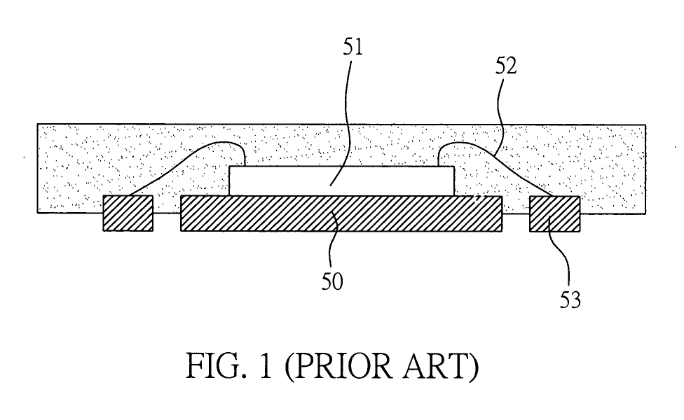

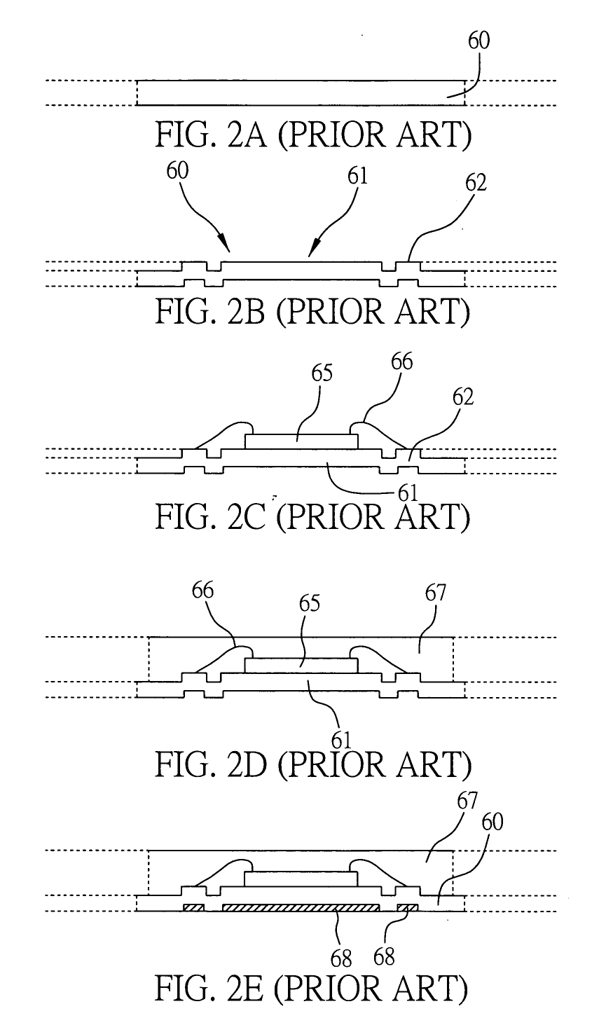

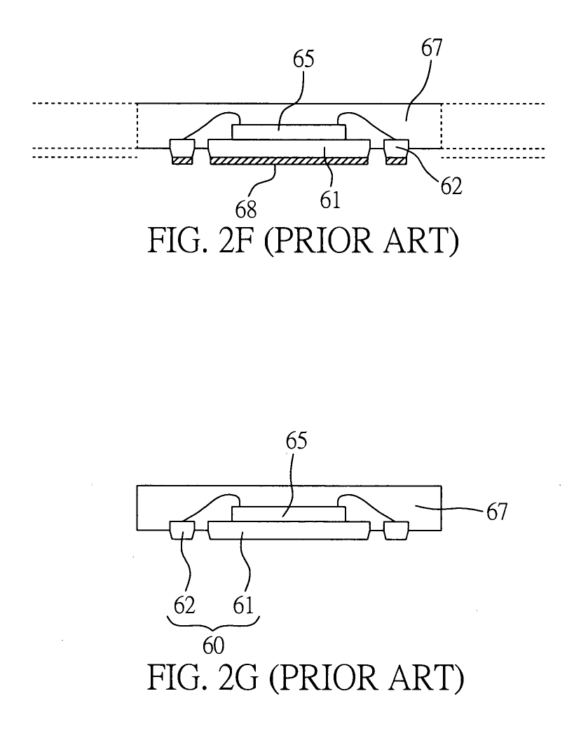

### DETAILED DESCRIPTION OF PREFERRED EMBODIMENTS

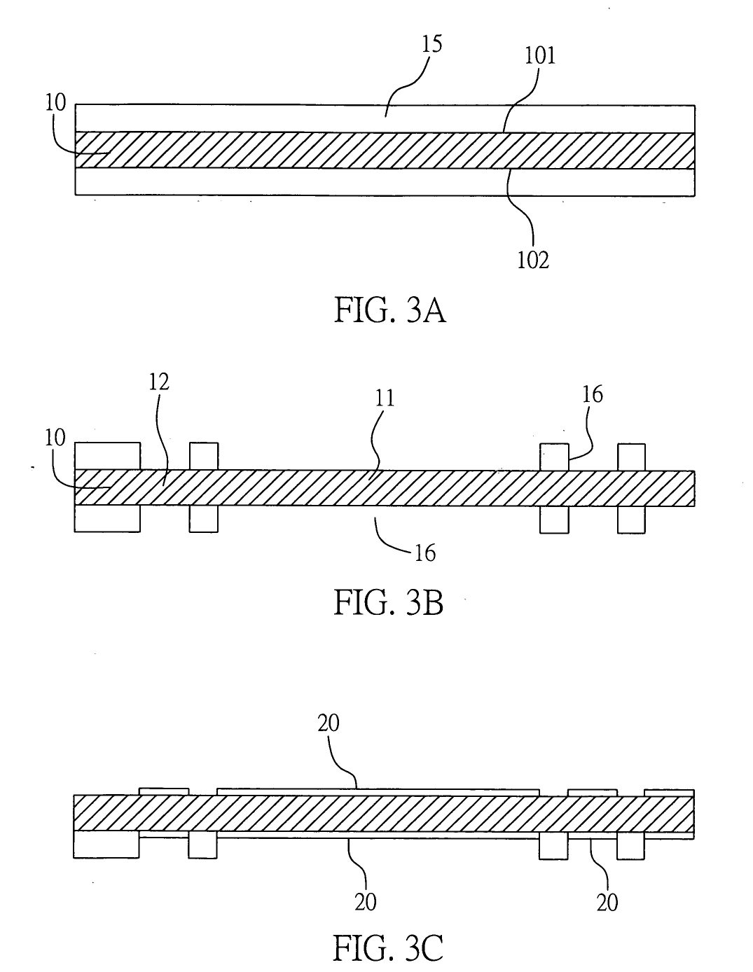

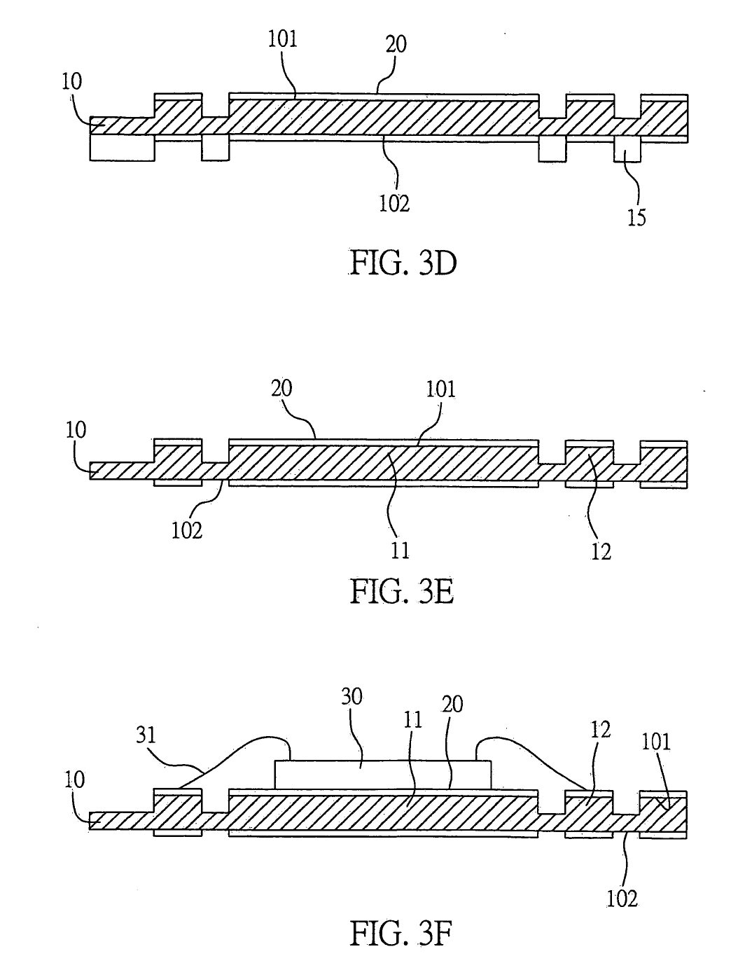

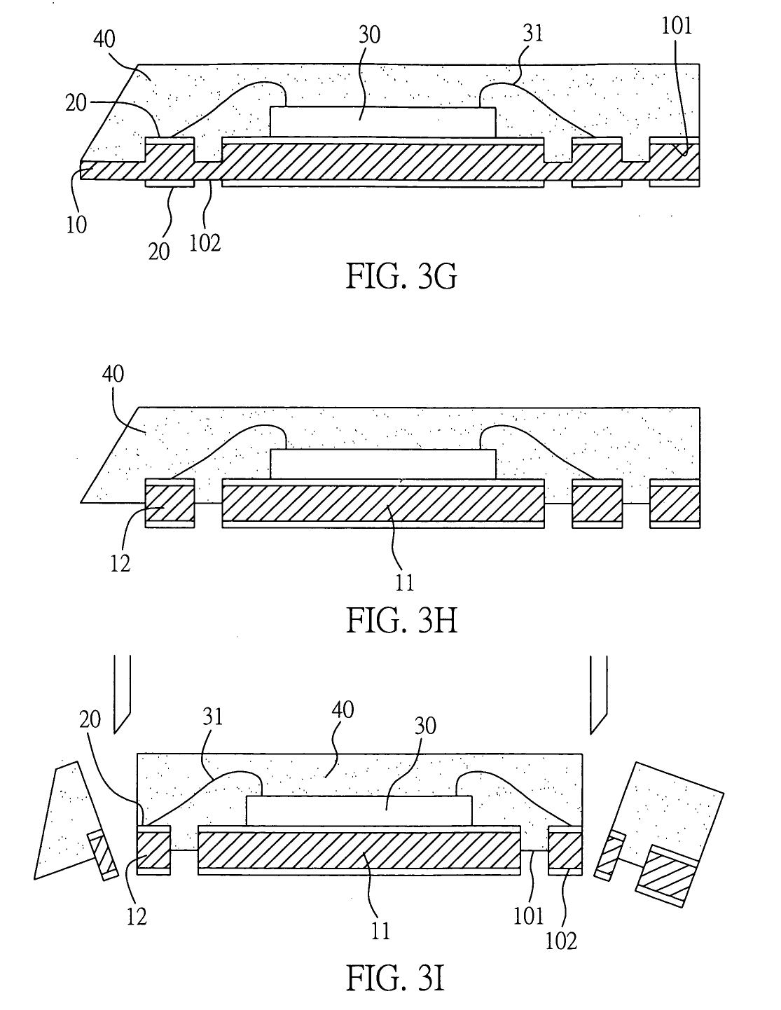

Preferred embodiments of a method of manufacturing a quad flat non-leaded semiconductor package as proposed in the present invention are described as follows with reference to FIGS. 3 to 6. It should be understood that the drawings are schematic diagrams only showing the relevant component for the present invention, and the component layout could be more complicated in practical implementation.

FIGS. 3A to 3I show steps of a method of manufacturing a quad flat non-leaded semiconductor package according to a first embodiment of the present invention. As shown in FIG. 3A, a metal plate 10 made of such as copper is firstly prepared. The metal plate 10 has a first surface 101 and an opposed second surface 102. As the first surface 101 of the metal plate 10 serves as a die-bonding surface, it is defined with predetermined positions of a die pad 11 and a plurality of electrically conductive pads 12, wherein the positions of the electrically conductive pads 12 are located around the position of the die pad 11.

A resist layer 15 such as a dry film is formed on each of the first and second surfaces 101, 102 of the metal plate 10, and serves as a photoresist layer for use in subsequent exposure, development and etching processes. As shown in FIG. 3B, a plurality of openings 16 are formed in the resist layers 15 on the first and second surfaces 101, 102 of the metal plate 10 by the exposure, development and etching processes and correspond to the predetermined positions of the die pad 11 and the electrically conductive pads 12. Then, a metal plated layer 20 is formed in each of the openings 16 of the resist layers 15 by plating. The metal plated layer 20 has at least four layers preferably including gold/palladium/nickel/palladium (Au/Pd/Ni/Pd) layers. Then, the resist layer 15 on the first surface 101 of the metal plate 10 is removed, such that only the metal plated layers 20 are left on the first surface 101 of the metal plate 10, as shown in FIG. 3C.

As shown in FIG. 3D, an etching process is performed on the first surface 101 of the metal plate 10, wherein the metal plated layers 20 on the first surface 101 of the metal plate 10 are used as a mask, and a portion of the metal plate 10, which is not covered by the metal plated layers 20, is etched downwardly. Subsequently, as shown in FIG. 3E, the resist layer 15 on the second surface 102 of the metal plate 10 is removed. As a result, the strip-shaped metal plate 10 having the die pad 11 and the electrically conductive pads 12 is obtained.

As shown in FIG. 3F, a chip 30 is mounted to the position of the die pad 11 on the first surface 101 of the metal plate 10, wherein the position of the die pad 11 is formed with the metal plated layer 20 thereon. Then, a wire-bonding process is performed to electrically connect the chip 30 to the corresponding electrically conductive pads 12 through bonding wires 31 such as gold wires, wherein the positions of the electrically conductive pads 12 are formed with the metal plated layers 20 thereon. As shown in FIG. 3G, a molding process is performed such that the chip 30, the bonding wires 31 and the first surface 101 of the metal plate 10 are encapsulated by an encapsulant 40 made of such as a resin material. Both the second surface 102 of the metal plate 10 and the metal plated layers 20 on the second surface 102 of the metal plate 10 are exposed from the encapsulant 40.

After the molding process, since the die pad 11 and the plurality of electrically conductive pads 12 are still connected to each other, an etching process is performed directly on the second surface 102 of the metal plate 10 by using the metal plated layers 20 on the second surface 102 of the metal plate 10 as a mask, such that a portion of the copper plate 10, which is located between the die pad 11 and the plurality of electrically conductive pads 12, is completely etched away, making the die pad 11 and the electrically conductive pads 12 separated from each other, as shown in FIG. 3H. Finally, as shown in FIG. 3I, a singulation process is carried out to cut the encapsulant 40 and the copper plate 10 along peripheral portions of the electrically conductive pads 12, such that the quad flat non-leaded semiconductor package is obtained.

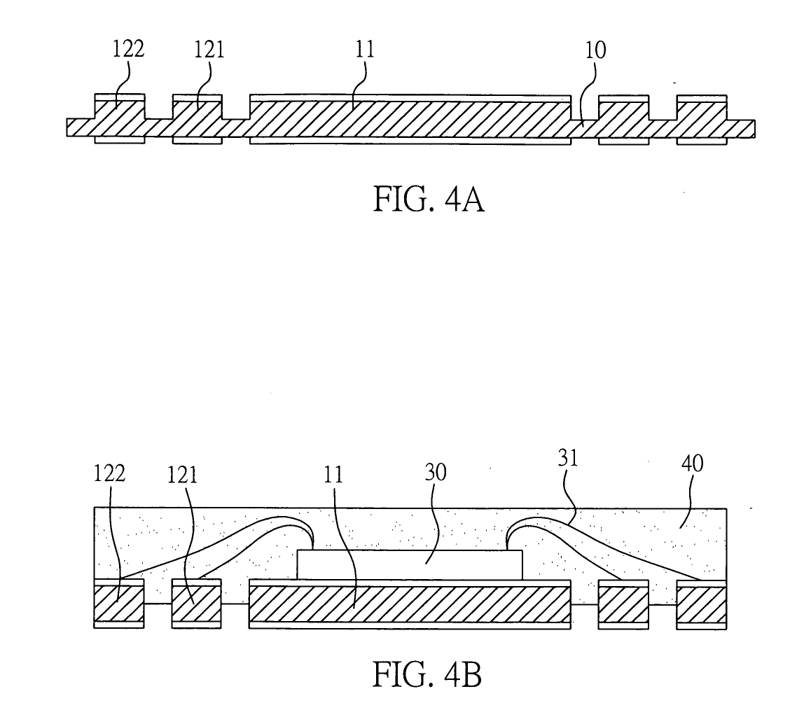

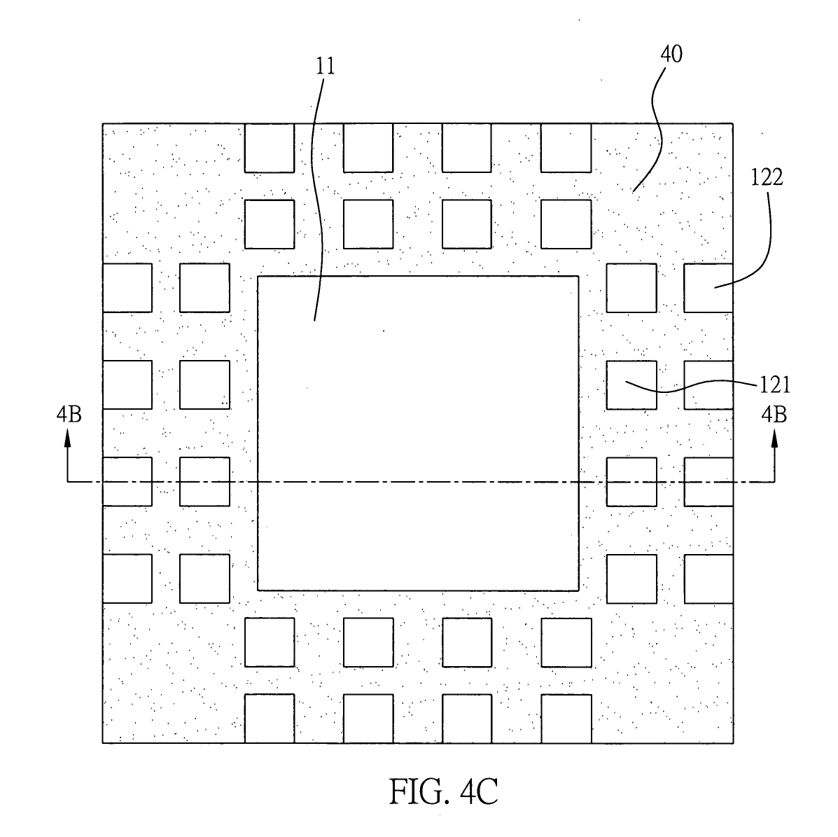

It should be noted that the arrangement of the electrically conductive pads is not limited to a single row of the electrically conductive pads 12 around the die pad 11 as described in the above first embodiment, but may also be multiple rows of electrically conductive pads as shown in FIGS. 4A, 4B and 4C according to a second embodiment of the present invention. As shown in FIG. 4A, the metal pad 10 is formed with the die pad 11, an inner row of electrically conductive pads 121 and an outer row of electrically conductive pads 122. After die-bonding, wire-bonding and molding processes are completed, an etching process is performed to separate the die pad 11, the inner row of electrically conductive pads 121 and the outer row of electrically conductive pads 122 from each other, as shown in a cross-sectional view of FIG. 4B and a bottom view of FIG. 4C.

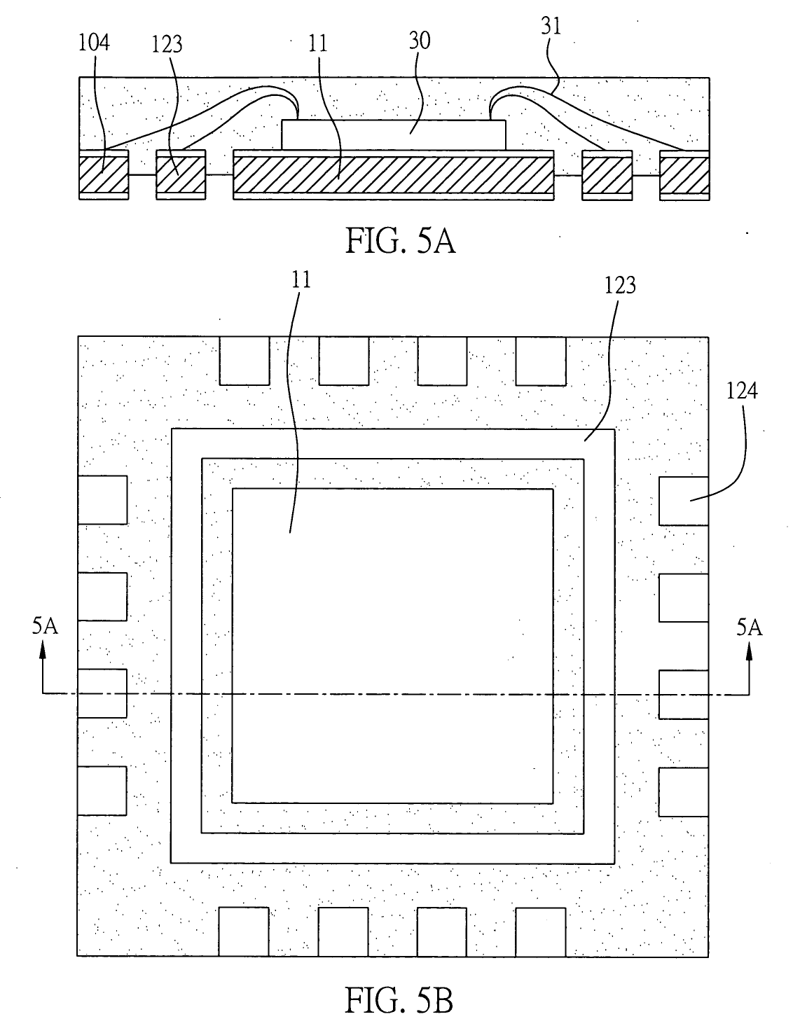

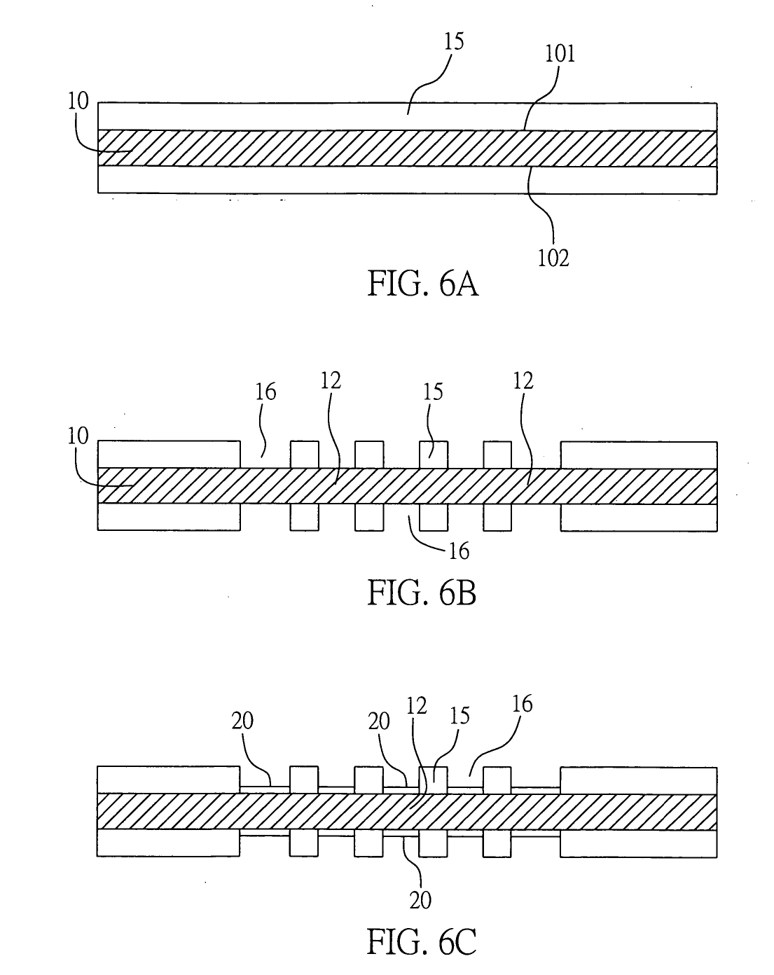

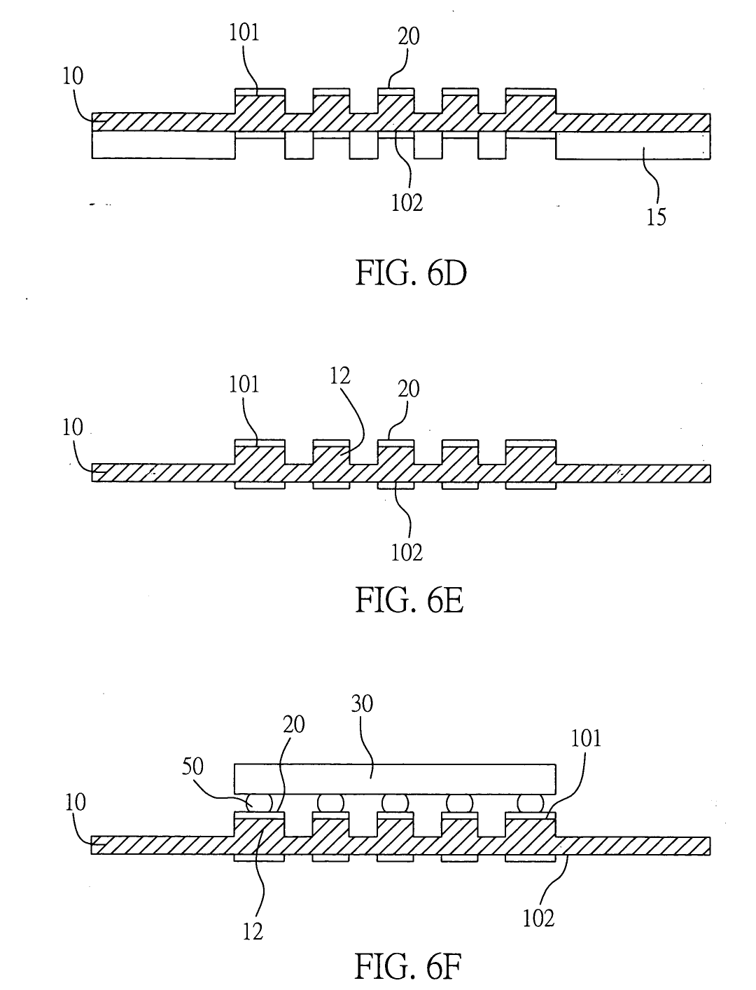

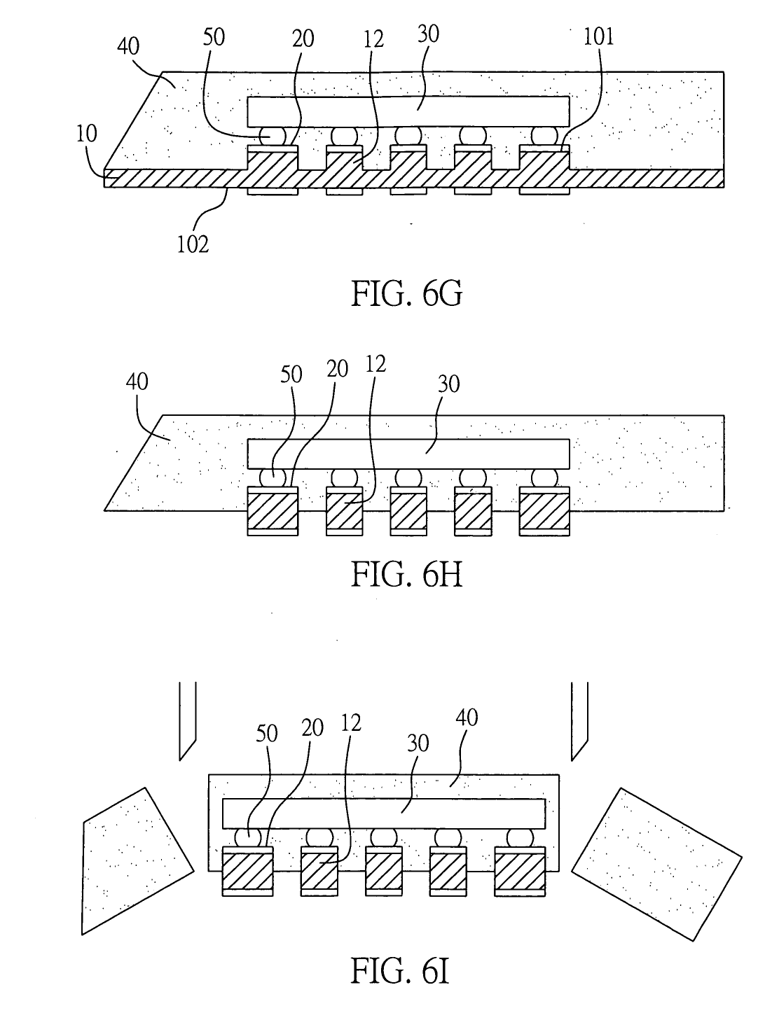

FIGS. 5A and 5B are respectively a cross-sectional view and a bottom view of a quad flat non-leaded semiconductor package according to a third embodiment of the present invention. The semiconductor package of the third embodiment is similar to that of the above embodiments, with a primary difference in that in the third embodiment, the metal plate is further defined with a position of a ground ring besides the positions of the die pad and the electrically conductive pads. As shown in FIGS. 5A and 5B, a ring-shaped structure such as a ground ring 123 is formed around the die pad 11 and a plurality of electrically conductive pads 124 are formed around the ground ring 123. When the chip 30 is mounted to the die pad 11, it can be electrically connected to both the ground ring 123 and the electrically conductive pads 124 by the bonding wires 31, thereby providing the chip 30 with grounding and signal transmission functions. In the foregoing embodiments, the chip 30 is electrically connected to the electrically conductive pads 12 via the bonding wires 31, which however does not set a limitation to the present invention. FIGS. 6A to 6I show steps of a method of manufacturing a quad flat non-leaded semiconductor package according to a fourth embodiment, wherein the chip 30 is electrically connected to the metal plate 10 through a flip-chip process. As shown in FIG. 6A, a metal plate 10 is firstly prepared, which has a first surface 101 and an opposed second surface 102, wherein the first surface 101 of the metal plate 10 is defined with predetermined positions of a plurality of electrically conductive pads 12. A resist layer 15 is formed on each of the first and second surfaces 101, 102 of the metal plate 10. Then, as shown in FIG. 6B, a plurality of openings 16 are formed in the resist layers 15 and correspond to the predetermined positions of the electrically conductive pads 12. Then, as shown in FIG. 6C, a metal plated layer 20 is formed in each of the openings 16 of the resist layers 15 by plating. As shown in FIG. 6D, the resist layer 15 on the first surface 101 of the metal plate 10 is removed. An etching process is performed on the first surface 101 of the metal plate 10, such that a portion of the metal plate 10, which is not covered by the metal plated layers 20, is etched. Subsequently, as shown in FIG. 6E, the resist layer 15 on the second surface 102 of the metal plate 10 is removed. As shown in FIG. 6F, a chip 30 is mounted to the first surface 101 of the metal plate 10 in a flip-chip manner such that the chip 30 is electrically connected to the corresponding electrically conductive pads 12 through a plurality of conductive bumps 50.

Then, as shown in FIG. 6G, a molding process is performed such that the chip 30, the conductive bumps 50 and the first surface 101 of the metal plate 10 are encapsulated by an encapsulant 40. Moreover, as shown in FIG. 6H, an etching process is performed on the second surface 102 of the metal plate 10 so as to separate the electrically conductive pads 12 from each other. Finally, as shown in FIG. 6I, a singulation process is carried out to obtain the quad flat non-leaded semiconductor package according to the fourth embodiment of the present invention.

Therefore, the method of the present invention allows the plating process of forming the metal plated layers and a lithography process to be completed on a panel-shaped metal plate, instead of a strip-shaped metal plate, before the molding process. That is, after defining the die pad and the electrically conductive pads, the fabrication processes such as die bonding, forming electrical connection and molding are performed, and then only a simple etching step is needed after the molding process to fabricate the quad flat non-leaded semiconductor package. Thus, the present invention has reduced difficulty and cost of the fabrication processes as not requiring the electroless plating and lithography processes in the prior art after the molding process, and the present invention also improves the product yield of the quad flat non-leaded semiconductor package and provides a metal plated layer having better solderability.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method of manufacturing a quad flat non-leaded semiconductor package, comprising the steps of:
preparing a metal plate having a first surface and an opposed second surface, wherein the first surface of the metal plate is defined with predetermined positions of a plurality of electrically conductive pads;
forming a resist layer on each of the first and second surfaces of the metal plate;
forming a plurality of openings in the resist layers on the first and second surfaces of the metal plate, the openings corresponding to the predetermined positions of the electrically conductive pads;
forming a metal plated layer in each of the openings of the resist layers on the first and second surfaces of the metal plate;
removing the resist layer on the first surface of the metal plate;
performing an etching process on the first surface of the metal plate, such that a portion of the metal plate, which is not covered by the metal plated layers, is etched;
removing the resist layer on the second surface of the metal plate;
mounting a chip on the first surface of the metal plate and electrically connecting the chip to the electrically conductive pads;
performing a molding process to form an encapsulant for encapsulating the chip and the first surface of the metal plate;
etching the second surface of the metal plate to separate the electrically conductive pads from each other; and
performing a singulation process such that the quad flat non-leaded semiconductor package is obtained.

2. The method of claim 1, wherein the chip is electrically connected to the electrically conductive pads by one of bonding wires and conductive bumps.

3. The method of claim 1, wherein the metal plated layers are formed on the predetermined positions of the electrically conductive pads.

4. The method of claim 1, wherein the metal plate is further defined with a position of a die pad for mounting the chip thereon.

5. The method of claim 4, wherein the metal plate is further formed with a metal plated layer on the position of the die pad.

6. The method of claim 4, wherein the positions of the electrically conductive pads are located around the position of the die pad.

7. The method of claim 4, wherein the resist layers are further formed with openings corresponding to the position of the die pad.

8. The method of claim 4, wherein the metal plate is further defined with a position of a ground ring.

9. The method of claim 8, wherein the position of the ground ring is located around the position of the die pad.

10. The method of claim 9, wherein the electrically conductive pads are located around the ground ring.

11. The method of claim 1, wherein the metal plate is made of copper.

12. The method of claim 1, wherein the electrically conductive pads are arranged in a single row.

13. The method of claim 1, wherein the electrically conductive pads are arranged in multiple rows.

14. The method of claim 1, wherein the resist layer is a photoresist layer.

15. The method of claim 1, wherein the openings of the resist layers are formed by exposure, development and etching.

16. The method of claim 1, wherein the metal plated layer has at least four layers including gold/palladium/nickel/palladium (Au/Pd/Ni/Pd) layers.

17. The method of claim 1, wherein the metal plated layers on the first surface of the metal plate serve as a mask during etching the first surface of the metal plate.

18. The method of claim 1, wherein the encapsulant is made of a resin material.

19. The method of claim 1, wherein the second surface of the metal plate is exposed from the encapsulant.

20. The method of claim 1, wherein the metal plated layers on the second surface of the metal plate serve as a mask during etching the second surface of the metal plate.
